(19) United States
(12) Patent Application Publication
(10) Pub. No.: US 2015/0021163 A1
(43) Pub. Date: Jan. 22, 2015

(54) APPARATUS AND METHOD FOR PRODUCING SOLAR CELLS WITH A HEATER APPARATUS

(71) Applicant: TSMC Solar Ltd., Taichung City (TW)

(72) Inventors: Wei-Lun LU, Tainan City (TW); Chun-Ying HUANG, Taichung City (TW); Wen-Chin LEE, Baoshan Township (TW)

(21) Appl. No.: 13/942,748

(22) Filed: Jul. 16, 2013

(51) Int. Cl. H01L 31/18

(52) U.S. Cl. CPC H01L 31/1876
USPC 204/192.1; 204/298.09

(57) ABSTRACT

A method and apparatus for forming a solar cell can include a heater apparatus having one or more heater elements in a deposition processing system, a front cover covering the one or more heater elements from a front side, and a back metal reflector mating with the front cover on a back side and enclosing the one or more heater elements. The method can include disposing a plurality of substrates about a plurality of surfaces of a substrate apparatus that is operatively coupled to sequentially feed a substrate within a vacuum chamber, forming an absorber layer over a surface of each one of the plurality of substrates and heating the surface of each one of the plurality of substrates with the heater apparatus as described above.

### FIELD

The present disclosure relates generally to the field of photovoltaics, and more specifically to an apparatus and method for producing solar cells using a heater apparatus.

### BACKGROUND

Copper indium gallium diselenide (CIGS) is a commonly used absorber layer in thin film solar cells. CIGS thin film solar cells have achieved excellent conversion efficiency (>20%) in laboratory environments. Most conventional CIGS deposition is done by one of two techniques: co-evaporation or selenization. Co-evaporation involves simultaneously evaporating copper, indium, gallium and selenium. The different melting points of the four elements makes controlling the formation of a stoichiometric compound on a large substrate very difficult. Additionally, film adhesion is very poor when using co-evaporation. Selenization involves a two-step process. First, a copper, gallium, and indium precursor is sputtered on to a substrate. Second, selenization occurs by reacting the precursor with toxic H2Se/H2S at 500° Celsius or above.

### BRIEF DESCRIPTION OF THE DRAWINGS

Various aspects of the present disclosure will be or become apparent to one with skill in the art by reference to the following detailed description when considered in connection with the accompanying exemplary non-limiting embodiments.

FIG. 1 is a schematic diagram illustrating a top view of an example of a solar cell forming apparatus according to embodiments of the present disclosure.

FIG. 2 is an exploded view of a heating apparatus used for example in forming a solar cell according to some embodiments.

FIG. 3 is a schematic diagram illustrating a top view of an example of a solar cell forming apparatus including the heating apparatus according to some embodiments.

FIG. 4 is a schematic diagram illustrating a top or side view of an example of a heating apparatus used with a rotating processing system for a solar cell forming apparatus according to some embodiments.

FIG. 5 is a schematic diagram illustrating a top or side view of an example of a heating apparatus using with an in-line processing system for a solar cell forming apparatus according to embodiments of the present disclosure.

FIG. 6 is a schematic diagram illustrating a side view of an example of a back metal reflective panel with grooves for a solar cell forming apparatus according to some embodiments.

FIG. 7 schematic diagram illustrating a side view of an example of a back metal reflective panel with grooves and a reflective metal coating for a solar cell forming apparatus according to some embodiments.

FIG. 8 schematic diagram illustrating the side view of the example of FIG. 7 and further including infrared heating sources and the reflected thermal patterns directed towards a substrate (not shown) according to some embodiments.

FIG. 9 schematic diagram illustrating the side view of an example of a planar back metal reflective panel and infrared heating sources and the reflected thermal patterns disbursed in a pattern as shown according to some embodiments.

FIG. 10 is a flow chart illustrating a method of forming a solar cell according to embodiments of the present disclosure.

### DETAILED DESCRIPTION OF THE EXAMPLES

With reference to the figures, where like elements have been given like numerical designations to facilitate an understanding of the drawings, the various embodiments of solar cell or a multi-gate semiconductor device and methods of forming the same are described. The figures are not drawn to scale.

The following description is provided as an enabling teaching of a representative set of examples. Many changes can be made to the embodiments described herein while still obtaining beneficial results. Some of the desired benefits discussed below can be obtained by selecting some of the features or steps discussed herein without utilizing other features or steps. Accordingly, many modifications and adaptations, as well as subsets of the features and steps described herein are possible and may even be desirable in certain circumstances. Thus, the following description is provided as illustrative and is not limiting.

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present disclosure. Relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected,” refer to a relationship wherein structures are secured or attached to one another either directly or indirectly through intervening structures, as well as both movable or rigid attachments or relationships, unless expressly described otherwise. The term “adjacent” as used herein to describe the relationship between structures/components includes both direct contact between the respective structures/components referenced and the presence of other intervening structures/components between respective structures/components.

As used herein, use of a singular article such as “a,” “an” and “the” is not intended to exclude pluralities of the article's object unless the context clearly and unambiguously dictates otherwise.

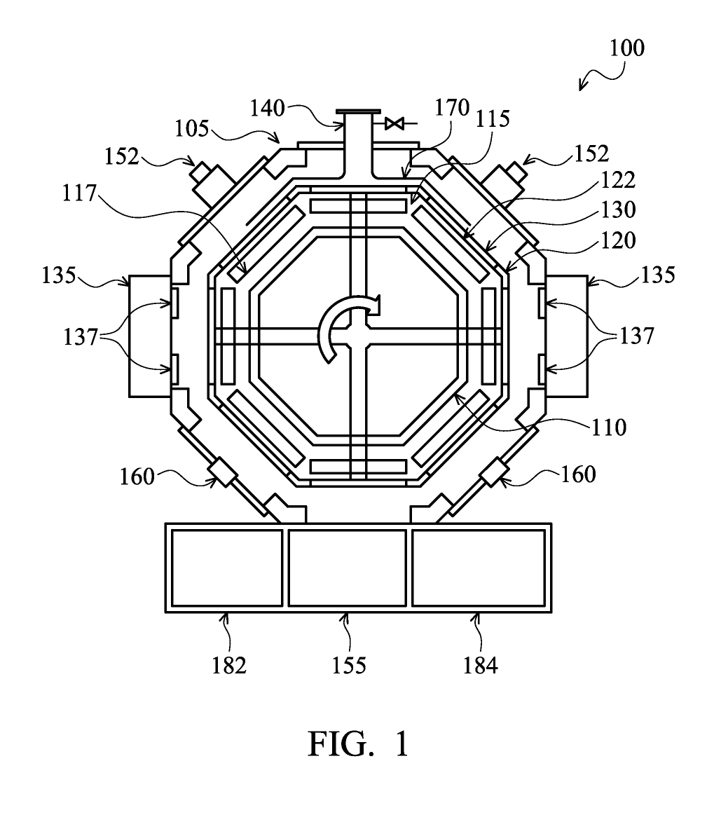

FIG. 1 is a schematic diagram illustrating a top view of an example of a solar cell forming apparatus 100 according to embodiments of the present disclosure. As shown, a solar cell forming apparatus 100 includes a housing 105 defining a vacuum chamber. In various embodiments, the housing 105 may be shaped as a polygon. For example, as shown in the illustrated embodiment, the housing 105 may be octagonally shaped. In various embodiments, the housing 105 has one or more removable doors built on one or more sides of the vacuum chamber. The housing 105 may be composed of stainless steel or other metals and alloys used for drum coater housings. For example, the housing 105 can define a single vacuum chamber having a height of approximately 2.4 m (2.3 m to 2.5 m) with a length and width of approximately 9.8 m (9.7 m to 9.9 m).

In some embodiments, the solar cell forming apparatus 100 includes a rotatable substrate apparatus 120 configured to hold a plurality of substrates 130 on a plurality of surfaces 122 where each of the plurality of surfaces 122 are disposed facing an interior surface of the vacuum chamber. In some embodiments, each one of the plurality of substrates 130 include a suitable material such as, for example, glass. In other embodiments, one or more of the plurality of substrates 130 include a flexible material. In some embodiments, the flexible material includes stainless steel. In other embodiments, the flexible material includes plastic. In various embodiments, the rotatable substrate apparatus 120 is shaped as a polygon. For example, in the illustrated embodiment, a plurality of substrates 130 are held on a plurality of surfaces 122 in a substantially octagonal shaped rotatable substrate apparatus 120. In other embodiments, for example, the substrate apparatus 120 may be rectangular shaped. Any suitable shape can be used for the rotatable substrate apparatus 120. Other embodiments can alternatively be in-line processed rather that rotatable as will be further discussed with respect to FIG. 5.

As shown in FIG. 1, the substrate apparatus 120 is rotatable about an axis in the vacuum chamber. FIG. 1 illustrates a clockwise direction of rotation for the rotatable substrate apparatus 120. In some embodiments, substrate apparatus 120 is configured to rotate in a counter-clockwise direction. In various embodiments, the rotatable substrate apparatus 120 is operatively coupled to a drive shaft, a motor, or other mechanism that actuates rotation from a surface of the vacuum chamber. In some embodiments, substrate apparatus 120 is rotated at a speed, for example, between approximately 5 and 100 RPM (e.g. 3 and 105 RPM). In various embodiments, a speed of rotation of the rotatable substrate apparatus 120 is selected to minimize excessive deposition of absorption components on the plurality of substrates 130. In some embodiments, the substrate apparatus rotates at a speed of approximately 80 RPM (e.g. 75-85 RPM). In some embodiments, the apparatus 100 includes a rotatable drum 110 disposed within the vacuum chamber and coupled to a first surface of the vacuum chamber. As illustrated in FIG. 1, the rotatable drum 110 can be disposed within the vacuum chamber. In the illustrated embodiment, the rotatable drum 110 is operatively coupled to the substrate apparatus 120. As shown, the rotatable drum 110 has a shape that is substantially conformal with the shape of the substrate apparatus 120. However, the rotatable drum can have any suitable shape.

In various embodiments, the apparatus 100 includes a first sputtering source 135 configured to deposit a plurality of absorber layer atoms of a first type over at least a portion of a surface of each one of the plurality of substrates 130. As shown in the illustrated embodiment, the first sputtering source 135 can be disposed within a vacuum chamber between the substrate apparatus 120 and the housing. The first sputtering source 135 can be coupled to a surface of the vacuum chamber. The first sputtering source 135 can be, for example, a magnetron, an ion beam source, a RF generator, or any suitable sputtering source configured to deposit a plurality of absorber layer atoms of a first type over at least a portion of a surface of each one of the plurality of substrates 130. In some embodiments, the first sputtering source 135 includes at least one of a plurality of sputtering targets 137. The first sputtering source 135 can utilize a sputtering gas. In some embodiments, sputtering is performed with an argon gas. Other possible sputtering gases include krypton, xenon, neon, and similarly inert gases.

As shown in FIG. 1, apparatus 100 can include a first sputtering source 135 disposed within the vacuum chamber and configured to deposit a plurality of absorber layer atoms of a first type over at least a portion of a surface of each one of the plurality of substrates 130 and a second sputtering source 135 disposed within the vacuum chamber and opposite the first sputtering source and configured to deposit a plurality of absorber layer atoms of a second type over at least a portion of a surface of each one of the plurality of substrates 130. In other embodiments, the first sputtering source 135 and the second sputtering source 135 are disposed adjacent to each other within the vacuum chamber. In some embodiments, the first and second sputtering sources 135 can each include at least one of a plurality of sputtering targets 137.

In various embodiments, a first sputtering source 135 is configured to deposit a plurality of absorber layer atoms of a first type (e.g. copper (Cu)) over at least a portion of a surface of each one of the plurality of substrates 130 and a second sputtering source 135 is configured to deposit absorber layer atoms of a second type (e.g. indium (In)) over at least a portion of a surface of each one of the plurality of substrates 130. In some embodiments, the first sputtering source 135 is configured to deposit a plurality of absorber layer atoms of a first type (e.g. copper (Cu)) and a third type (e.g. gallium (Ga)) over at least a portion of a surface of each one of the plurality of substrates 130. In some embodiments, a first sputtering source 135 includes one or more copper-gallium sputtering targets 137 and a second sputtering source 135 includes one or more indium sputtering targets 137. For example, a first sputtering source 135 can include two copper-gallium sputtering targets and a second sputtering source 135 can include two indium sputtering targets. In some embodiments, a copper-gallium sputtering target 137 includes a material of approximately 70 to 80% (e.g. 69.5 to 80.5%) copper and approximately 20 to 30% (e.g. 19.5 to 30.5%) gallium. In various embodiments, the solar cell forming apparatus 100 has a first copper-gallium sputtering target 137 at a first copper: gallium concentration and a second copper-gallium sputtering target 137 at a second copper: gallium concentration for grade composition sputtering. For example, a first copper-gallium sputtering target can include a material of 65% copper and 35% gallium to control monolayer deposition to a first gradient gallium concentration and a second copper-gallium sputtering target can include a material of 85% copper and 15% gallium to control monolayer deposition to a second gradient gallium concentration. The plurality of sputtering targets 137 can be any suitable size. For example, the plurality of sputtering targets 137 can be approximately 15 cm wide (e.g. 14-16 cm) and approximately 1.9 m tall (e.g. 1-8-2.0 m).

In some embodiments, a sputtering source 135 that is configured to deposit a plurality of absorber layer atoms of indium over at least a portion of the surface of each one of the plurality of substrates 130 can be doped with sodium (Na). For example, an indium sputtering target 137 of a sputtering source 135 can be doped with sodium (Na) elements. Doping an indium sputtering target 137 with sodium may minimize the need for depositing an alkali-silicate layer in the solar cell. This improvement may result in lower manufacturing costs for the solar cell as sodium is directly introduced to the absorber layer. In some embodiments, a sputtering source 135 is a sodium-doped copper source having between approximately two and ten percent sodium (e.g. 1.95 to 10.1 percent sodium). In various embodiments, an indium sputtering source 135 can be doped with other alkali elements such as, for example, potassium. In other embodiments, apparatus 100 can include multiple copper-gallium sputtering sources 135 and multiple sodium doped indium sputtering sources 135. For example, the solar cell forming apparatus can have a 65:35 copper-gallium sputtering source 135 and an 85:15 copper-gallium sputtering source 135 for grade composition sputtering.

In various embodiments, apparatus 100 includes an evaporation source 140 configured to deposit a plurality of absorber layer atoms of a fourth type over at least a portion of the surface of each one of the plurality of substrates 130. In various embodiments, the fourth type is non-toxic elemental selenium. The fourth type can include any suitable evaporation source material. In some embodiments, evaporation source 140 is configured to produce a vapor of an evaporation source material of the fourth type. In various embodiments, the vapor can condense upon the one or more substrates 130. For example, the evaporation source 140 can be an evaporation boat, crucible, filament coil, electron beam evaporation source, or any suitable evaporation source 140. In some embodiments, the evaporation source 140 is disposed in a first subchamber of the vacuum chamber 110. In various embodiments, the vapor of the fourth type evaporation source material can be ionized, for example using an ionization discharger, prior to condensation over the substrate to increase reactivity. In the illustrated embodiment, a first and second sputtering source 135 are disposed on opposing sides of the vacuum chamber and substantially equidistant from evaporation source 140 about the perimeter of the vacuum chamber.

In various embodiments, apparatus 100 includes a first isolation source configured to isolate an evaporation source 140 from a first sputtering source 135. The first isolation source can be configured to prevent fourth type material from evaporation source 140 from contaminating the first sputtering source 135. In the illustrated embodiment, the first isolation source is an isolation pump 152, such as, for example, a vacuum pump. In other embodiments, the apparatus 100 can include a plurality of isolation pumps 152. In various embodiments, the isolation source can include a combination of an isolation pump 152 and an isolation subchamber (not shown).

In some embodiments, the first isolation pump can include a vacuum pump 152 disposed within a first subchamber of the vacuum chamber to maintain the pressure in the first subchamber lower than the pressure in the vacuum chamber outside of the first subchamber. For example, the first isolation pump 152 can be disposed within a first subchamber of the vacuum chamber housing the evaporation source 140 to maintain the pressure in the first subchamber lower than the pressure in the vacuum chamber outside of the first subchamber and to isolate the evaporation source 140 from the first sputtering source. In various embodiments, the isolation source 152 can be an evacuation source 152 such as, for example, a vacuum pump 152 configured to evacuate atoms from the vacuum chamber to prevent contamination of a sputtering source 135. For example, isolation source 152 can be a vacuum pump 152 disposed within a first subchamber of the vacuum chamber housing the evaporation source 140 and configured to evacuate evaporation source material atoms to prevent contamination of a sputtering source 135. In various embodiments, isolation source 152 can be a vacuum pump disposed along a perimeter surface of the vacuum chamber and configured to evacuate atoms (e.g. evaporation source material atoms) from the vacuum chamber to prevent contamination of sputtering source 135.

In embodiments including a plurality of sputtering sources 135 and/or a plurality of evaporation sources 140, apparatus 100 can include a plurality of isolation sources to isolate each of the evaporation sources from each of the sputtering sources 135. For example, in embodiments having first and second sputtering sources 135 disposed on opposing sides of a vacuum chamber and an evaporation source 140 disposed there between on a perimeter surface of the vacuum chamber, apparatus 100 can include a first isolation pump 152 disposed between the first sputtering source 135 and evaporation source 140 and a second isolation pump 152 disposed between the second sputtering source 135 and evaporation source 140. In the illustrated embodiment, apparatus 100 includes an isolation pump 152 disposed between evaporation source 140 and one of the two sputtering sources 135.

The solar cell forming apparatus 100 can include one or more heaters 117 to heat the plurality of substrates 130 disposed on a plurality of surfaces 122 of the rotatable substrate apparatus 120. In the illustrated embodiment, a plurality of heaters 117 are disposed in a heater apparatus 115 to heat the plurality of substrates. As shown in FIG. 1, heater apparatus 115 can have a shape that is substantially conformal with the shape of the substrate apparatus 120. In the illustrated embodiment, the plurality of heaters 117 are shown positioned in a substantially octagonal shape arrangement within a heating apparatus 115. However, the heater apparatus 115 can have any suitable shape. In various embodiments, the heater apparatus 115 is disposed to maintain a substantially uniform distance about the perimeter of the substrate apparatus 120. In the illustrated embodiment, heater apparatus 115 is disposed about an interior surface of the rotatable substrate apparatus 120. In some embodiments, the heater apparatus 115 can be disposed about an interior surface of a rotatable drum 110. A power source of the heater apparatus 115 can extend through a surface of the rotatable drum 110. In various embodiments, the substrate apparatus 120 is rotatable around the heater apparatus 115. In some embodiments, the heater apparatus 115 is disposed about an exterior surface of a rotatable drum 110. In some embodiments, the heater apparatus 115 can be coupled to a surface of the vacuum chamber. The heater apparatus 115 can be rotatable. In other embodiments, the heater apparatus 115 is configured to not rotate. The one or more heaters 117 can include, but are not limited to, infrared heaters, halogen bulb heaters, resistive heaters, microwave tube heaters, or any suitable heater for heating a substrate 130 during a deposition process. In some embodiments, the heater apparatus 115 can heat a substrate to a temperature between approximately 300 and 550 degrees Celsius (e.g. 295 and 555 degrees Celsius).

As shown in FIG. 1, apparatus 100 can include an isolation baffle 170 disposed about the evaporation source 140. Isolation baffle 170 can be configured to direct a vapor of an evaporation source material to a particular portion of a surface of the plurality of substrates 130. Isolation baffle 170 can be configured to direct a vapor of an evaporation source material away from a sputtering source 135. Apparatus 100 can include an isolation baffle 170 in addition to one or more isolation sources to minimize evaporation source material 122 contamination of one or more sputtering sources 135. The isolation baffle 170 can be composed of a material such as, for example, stainless steel or other similar metals and metal alloys. In some embodiments, the isolation baffle 170 is disposable. In other embodiments, the isolation baffle 170 is cleanable.

In some embodiments, apparatus 100 can include one or more in-situ monitoring devices 160 to monitor process parameters such as temperature, chamber pressure, film thickness, or any suitable process parameter. In various embodiments, apparatus 100, can include a load lock chamber 182 and/or an unload lock chamber 184. In embodiments of the present disclosure, apparatus 100 can include a buffer subchamber 155 (e.g. a buffer layer deposition subchamber) configured in-situ in apparatus 100 with a vacuum break. In some embodiments, a buffer layer deposition subchamber 155 configured in-situ in apparatus 100 with a vacuum break includes a sputtering source (not shown) including one or more sputtering targets (not shown). In various embodiments, apparatus 100 includes a sputtering source (not shown) disposed in a subchamber of the vacuum chamber and configured to deposit a buffer layer over a surface of each one of the plurality of substrates 130 in substrate apparatus 130. In various embodiments, apparatus 100 includes an isolation source to isolate the buffer layer sputtering source from an evaporation source and/or an absorber monolayer sputtering source. The buffer layer material can include, for example, non-toxic ZnS—O or CdS.

The apparatus 100 of FIG. 1 can also be used to form solar cells of different absorber films, for example, a copper-zinc-tin-sulfur-selenium (CZTSS) absorber film. In some embodiments, a number of CZTSS absorber layer are formed in apparatus 100 by further providing tin, copper, zinc, or copper/zinc targets. as targets 137. The evaporation source 140 may use sulfur, selenium or both sulfur and selenium as source material. Additionally, another evaporation source 140 may be used to separately provide selenium and sulfur source material.

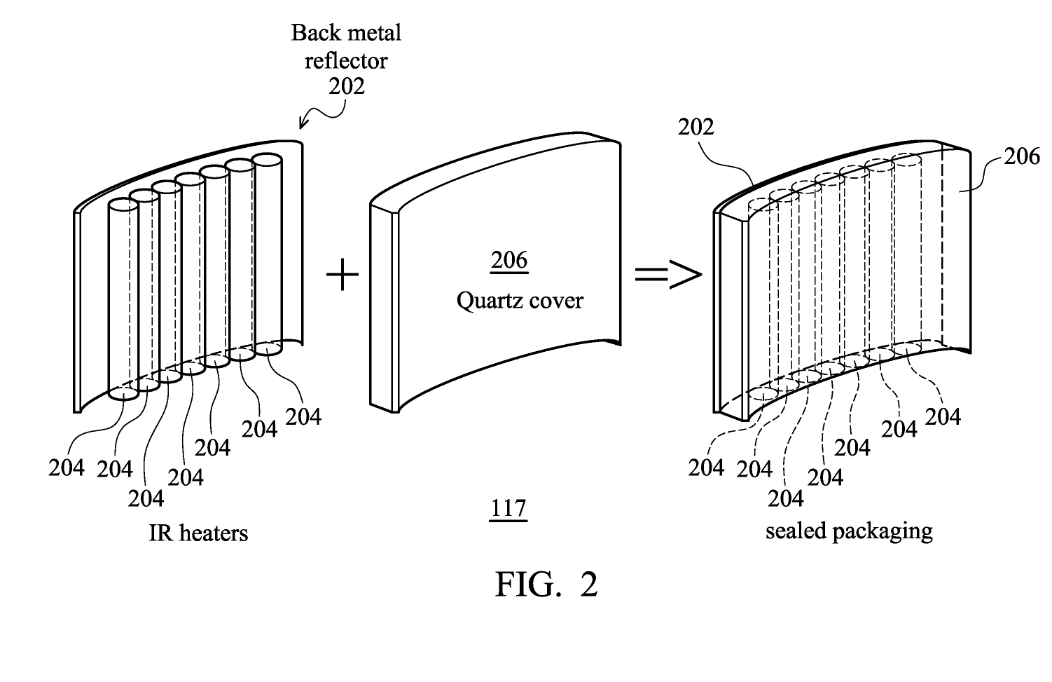

FIG. 2 is an exploded perspective view of the heater or heater module or heater apparatus 117 used for forming a solar cell. In one embodiment, the heater apparatus 117 includes one or more heater elements 204 for use in a deposition processing system, a front cover 206 covering the one or more heater elements 204 from a front side and a back metal reflector 202 mating with the front cover 206 on a back side and enclosing the one or more heater elements 204 with the heater apparatus 117. The front cover 206 can be made of quartz, graphite, silicon carbide, ceramic materials or any kind of material with high thermal conductivity. The deposition processing system can be for example a rotating deposition processing system or an in-line deposition processing system, or a vertical deposition processing system. The heater elements 204 can be infrared heater elements, but other heater elements can be used within contemplation of the embodiments herein as explained above. The back metal reflector can be one of planar shaped, arc shaped, or curved shaped to better conform to the shape of the deposition processing system. The back metal reflector can also include various shaped elements such as grooves, dimples or any other shape that would enhance the thermal irradiation focus on a surface of a substrate being processed by a deposition processing system.

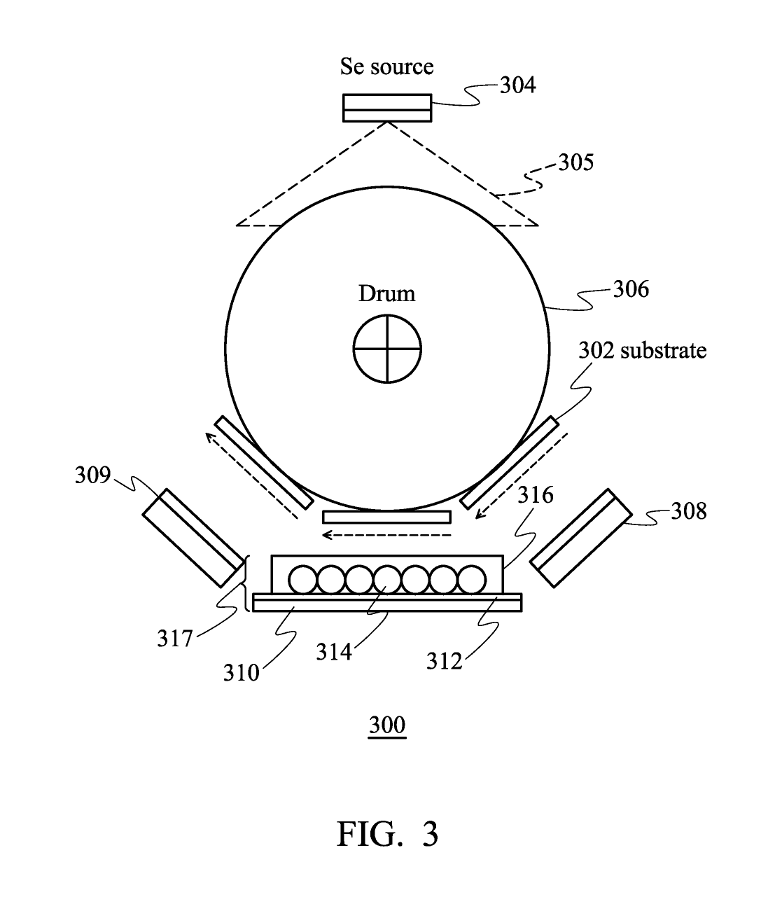

Referring to FIG. 3, a deposition processing system 300 can include a drum 306 that carries a plurality of substrates 302 for exposure to various processing steps in the deposition processing system 300. Each substrate 302 can be exposed to sputtering devices 308 and 309 and a heating apparatus 317 that can be placed between adjacent sputtering cathodes 308 and 309 of the deposition processing system. The heating apparatus 317 can include a stainless steel plate or some other form of back metal reflector 310 which can be further coated with a highly reflective metal coating 312 such as gold, aluminum, or copper. A plurality of heater elements 314 such as infrared heater elements are enclosed or encased between the back metal reflector 310 and a front cover such as a quart front cover 316. The system 300 can further include a selenium source 304 that applies selenium within an area 305. The front cover 316 can protect the heater elements 314 from contamination from selenium or other processing elements while still enabling sufficient thermal conductivity to heat the substrates being processed.

The substrates of a plurality of substrates are each sequentially fed in front or above the front quart cover of the heater apparatus for a predetermined period. The back metal reflector can be made of a planar stainless plate or of a grooved reflective metal plate or of a plate having other shapes that will enhance the focus or thermal irradiation towards a substrate being processed. Optionally, the back metal reflector includes a plate having a high-reflectivity metal coating 312. The high-reflectivity metal coating 312 can be made of gold, copper, or aluminum or any combination thereof. Of course other highly reflective metals or materials can be alternatively used. The back metal reflector can also optionally include shaped elements such as grooves that are then coated with the high reflectivity coating.

In one embodiment, the heater apparatus 117 or 317 resides within a housing defining a vacuum chamber of the deposition processing system 100 or 300 and where the deposition processing system further includes at least a first sputtering source (308 or 309) configured to deposit a plurality of absorber layer atoms of a first type over at least a portion of a surface of each one of a plurality of substrates (302) and at least an evaporation source disposed in a first subchamber of the vacuum chamber and configured to deposit a plurality of absorber layer atoms of a second type over at least a portion of the surface of each one of the plurality of substrates.

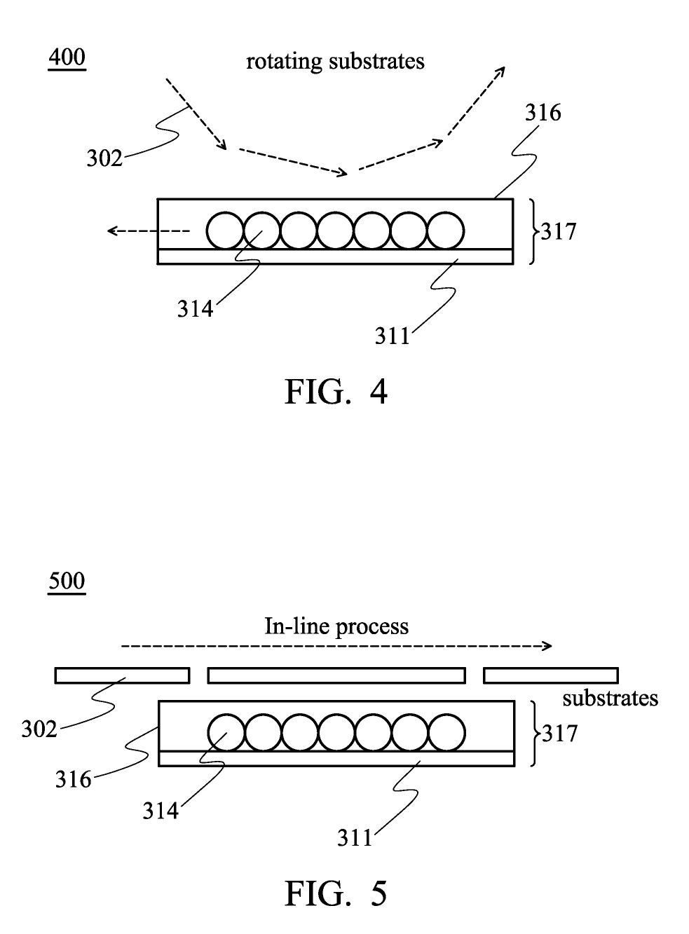

FIG. 4 illustrates a representation of a heater apparatus 317 having the heater elements 314 between the back metal reflector 311 and the front cover such as the quartz cover 316. The heater element 317 forms a part of a deposition processing system 400 that presents or feeds substrates 302 to the heating apparatus 317 in a rotating fashion. The deposition processing system 500 of FIG. 5 similarly includes the heater element 317 having the heater elements 314 between the back metal reflector 311 and the quartz cover 316. The heater element 317 forms a part of a deposition processing system 500 that presents or feeds substrates 302 to the heating apparatus 317 in an in-line fashion.

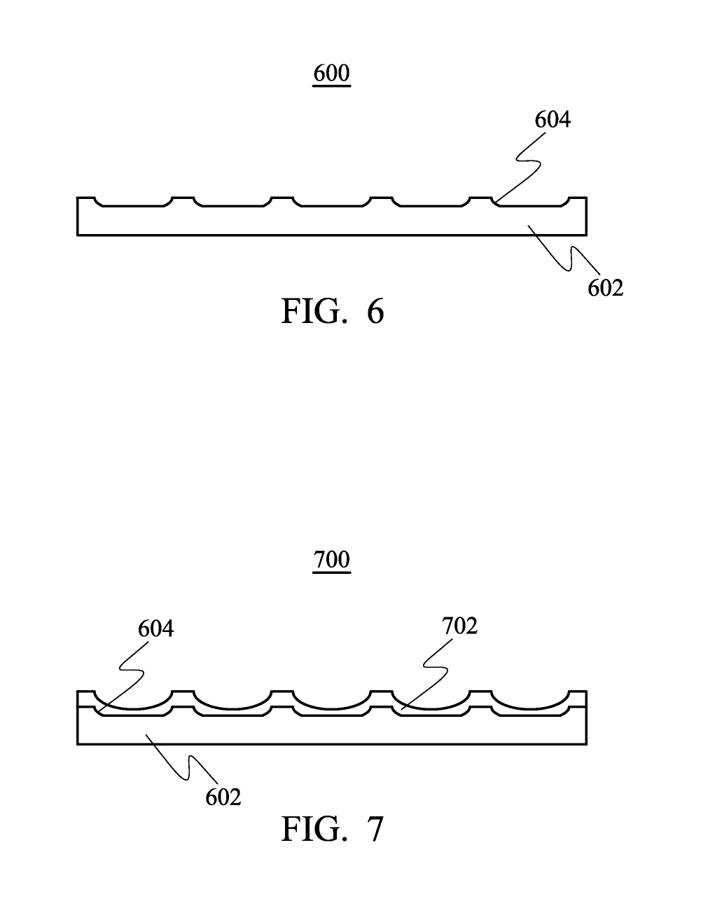

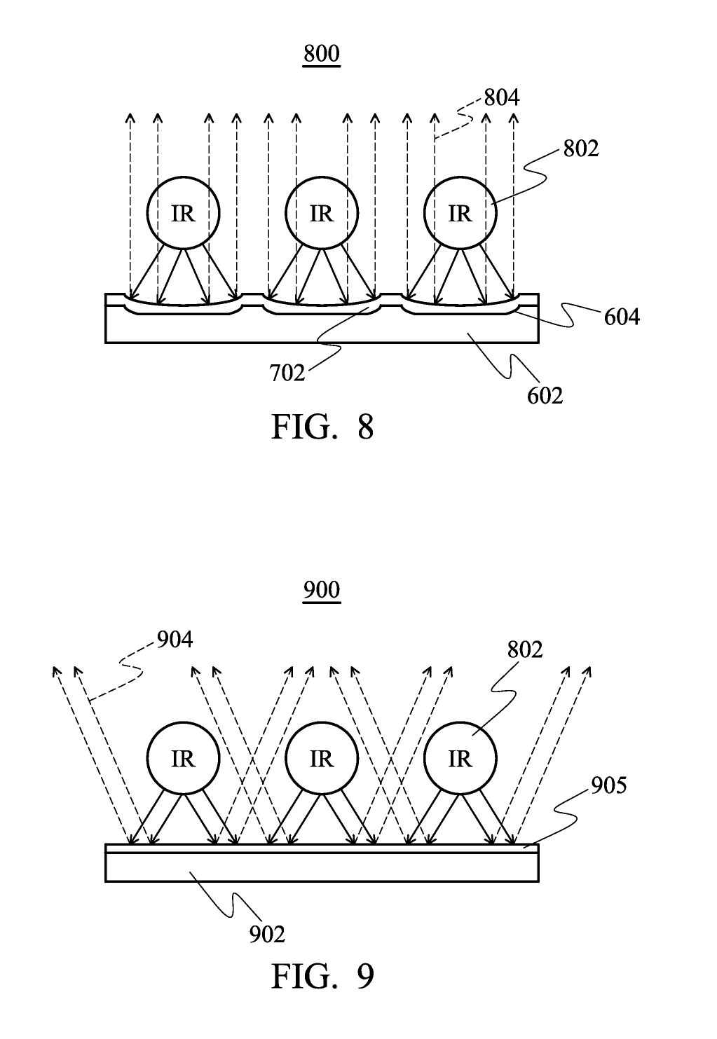

Referring to the representation 600 of FIG. 6, a back metal reflector 602 can include shaped elements such as grooves 604 as shown. The back metal reflector 602 can be formed of stainless steel for example. The back metal reflector can be made of other alternative metals and can also include other alternative shaped elements that focus thermal irradiation towards a substrate being processed. Referring to the representation 700 of FIG. 7, the back metal reflector 602 can further include a highly reflective metal layer 702 that can be made of gold, copper, or aluminum for example. The highly reflective metal layer 702 can be place above the grooves 604 as well. Referring to FIG. 8, the representation 800 can further include infrared heating sources 802 that are arranged above the reflective metal layer 702 and the grooves 604. The grooves 604 enable thermal reflections 804 that direct and concentrate heat toward a substrate (not shown) or the surface of a substrate that would reside directly above the back metal reflector 602. The representation 900 of FIG. 9 illustrates that a flat metal reflector 902 would have thermal reflections 904 that would tend to scatter and not be as efficiently focused or directed towards a substrate in process. However, a flat reflector surface is within contemplation of the embodiments herein.

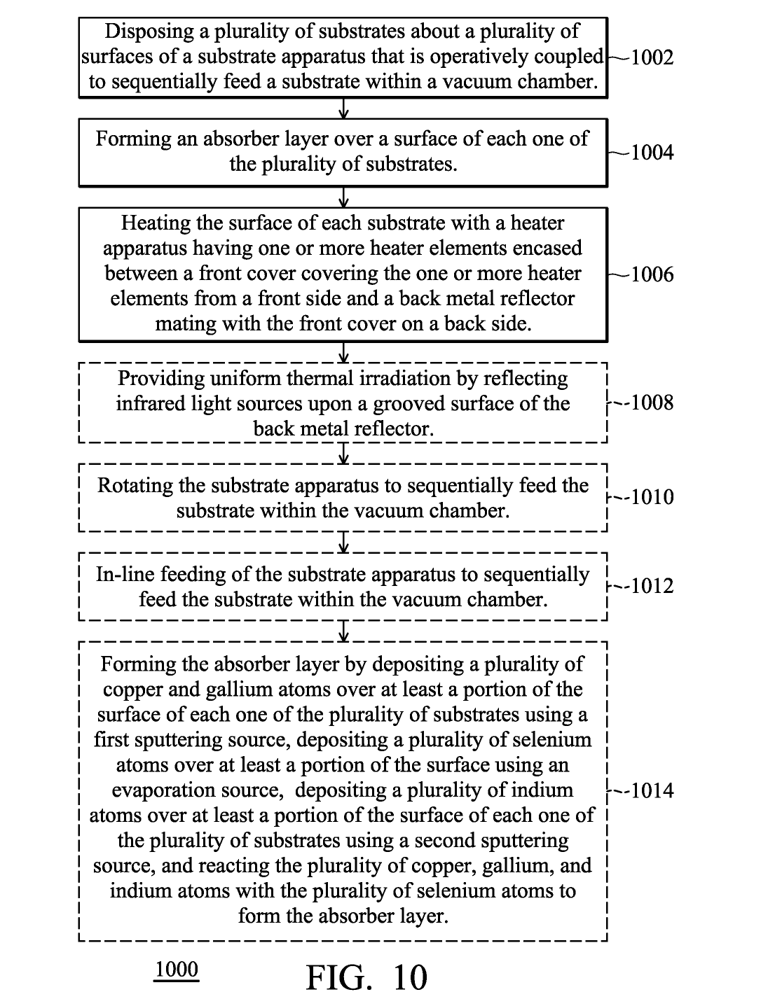

FIG. 10 is a flow chart illustrating a method 100 of forming a solar cell according to embodiments of the present disclosure. At block 1002, the method begins by disposing a plurality of substrates about a plurality of surfaces of a substrate apparatus that is operatively coupled to sequentially feed a substrate within a vacuum chamber and at 1004 forming an absorber layer over a surface of each one of the plurality of substrates. The method at 1006 proceeds by heating the surface of each one of the plurality of substrates with a heater apparatus having one or more heater elements encased between a front cover (such as a quartz front cover) covering the one or more heater elements from a front side and a back metal reflector mating with the quartz cover on a back side. At 1008, the method can provide uniform thermal irradiation by reflecting infrared light sources forming the one or more heater elements upon a shaped surface such as a grooved surface of the back metal reflector. In one embodiment, disposing at 1010 can include rotating the substrate apparatus to sequentially feed the substrate within the vacuum chamber and in another embodiment disposing at 1012 can alternatively include in-line feeding of the substrate apparatus to sequentially feed the substrate within the vacuum chamber. In another embodiment, forming the absorber layer can include at 1014 the steps of depositing a plurality of copper and gallium atoms over at least a portion of the surface of each one of the plurality of substrates using a first sputtering source, depositing a plurality of selenium atoms over at least a portion of the surface using an evaporation source, depositing a plurality of indium atoms over at least a portion of the surface of each one of the plurality of substrates using a second sputtering source and reacting the plurality of copper, gallium, and indium atoms with the plurality of selenium atoms to form the absorber layer.

In various embodiments and with reference to FIG. 1 again, forming the absorber layer can include a plurality of copper and gallium atoms deposited over at least a portion of the surface 122 of each one of the plurality of substrates 130 using a first sputtering source (e.g. 135). A plurality of selenium atoms can be deposited over at least a portion of the surface 122 of each one of the plurality of substrates 130 using an evaporation source (e.g. 140). A plurality of indium atoms are then deposited over at least a portion of the surface 122 of each one of the plurality of substrates 130 using a second sputtering source (e.g. 135). The plurality of copper, gallium, and indium atoms are then reacted with the plurality of selenium atoms to form the absorber monolayer.

In some embodiments, a plurality of copper and gallium atoms are deposited over at least a portion of the surface 122 of each one of the plurality of substrates 130 using a first sputtering source (e.g. 135). A plurality of indium atoms are then deposited over at least a portion of the surface 122 of each one of the plurality of substrates 130 using a second sputtering source (e.g. 135). Then, a plurality of selenium atoms are deposited over at least a portion of the surface 122 of each one of the plurality of substrates 130 using an evaporation source (e.g. 140). At block 838, the plurality of copper, gallium, and indium atoms are reacted with the plurality of selenium atoms to form the absorber monolayer.

Adjusting a power source of a sputtering source (e.g. first and/or second sputtering source 135) can control a sputtering rate and a concentration of the sputtered copper, gallium, and/or indium atoms deposited over the substrate 130. Similarly, adjusting a power source of an evaporation source 140 can control an evaporation rate and a concentration of the evaporated selenium atoms deposited over the substrate 130. The speed and/or direction of rotation of the substrate apparatus 120 also can affect the rate and amount of sputtered copper, gallium, and/or indium atoms and the amount of evaporated selenium atoms deposited over the substrate 130. As described above, selecting the copper-gallium concentration in one or more copper-gallium sputtering targets (e.g. 137) of one or more sputtering sources (e.g. 135) can control concentration of the sputtered copper and gallium atoms to a desired gradient concentration. In various embodiments, one or more of the power source of each sputtering source and each evaporation source, the sputtering rate of each sputtering source, the evaporation rate of each evaporation source is controlled to form a predetermined composition of an absorber monolayer. In various embodiments, the formed absorber monolayer includes a composition of 20 to 24% copper, 4 to 14% gallium, 10 to 24% indium and 49 to 53% selenium. In some embodiments, the composition is 23% copper, 9% gallium, 17% indium, 51% selenium. By using the methods and apparatus of forming the absorber monolayer described herein, an increased efficiency and accuracy for forming the absorber monolayer having the predetermined composition can be achieved.

In various embodiments, a plurality of selenium atoms are evacuated from the vacuum chamber using a first isolation pump (e.g. 152) disposed between the evaporation source 140 and the first sputtering source 135 and a second isolation pump (152) disposed between the evaporation source 140 and the second sputtering source 135. In various embodiments, a buffer layer is deposited over the absorber layer of each one of the plurality of substrates using a third sputtering source (e.g. 135) disposed in a subchamber (e.g. 155) of the vacuum chamber. In other embodiments, the absorber monolayers can comprise elements of other semiconductor compounds, including, but not limited to, ClSe, CGSe, CIS, CGS, CIGSe, CIGSeS, CZTS or any suitable compound to form an absorber layer of a solar cell.

Throughout the description and drawings, example embodiments are given with reference to specific configurations. It will be appreciated by those of ordinary skill in the art that the present disclosure can be embodied in other specific forms. Those of ordinary skill in the art would be able to practice such other embodiments without undue experimentation. The scope of the present disclosure, for the purpose of the present patent document, is not limited merely to the specific example embodiments or alternatives of the foregoing description.

As shown by the various configurations and embodiments illustrated in FIGS. 1-10 various improved CIGS films have been described, but the embodiments are not limited thereto.

According to some embodiments, the heater apparatus 117 includes one or more heater elements 204 for use in a deposition processing system, a front cover 206 covering the one or more heater elements 204 from a front side and a back metal reflector 202 mating with the front cover 206 on a back side and enclosing the one or more heater elements 204 with the heater apparatus 117. The enclosure formed by the front cover 206 and back metal reflector 202 can be sealed, but does not necessarily need to be sealed in all embodiments. The deposition processing system can be for example a rotating deposition processing system or an in-line deposition processing system, or a vertical deposition processing system. The heater elements 204 can be infrared heater elements, but other heater elements can be used within contemplation of the embodiments herein. The back metal reflector can be one of planar shaped, arc shaped, or curved shaped to better conform to the shape of the deposition processing system.

According to various embodiments, a method of forming a solar cell is provided. The method includes forming a solar cell according to embodiments of the present disclosure. At block 1002, the method begins by disposing a plurality of substrates about a plurality of surfaces of a substrate apparatus that is operatively coupled to sequentially feed a substrate within a vacuum chamber and at 1004 forming an absorber layer over a surface of each one of the plurality of substrates. The method at 1006 proceeds by heating the surface of each one of the plurality of substrates with a heater apparatus having one or more heater elements encased between a front cover covering the one or more heater elements from a front side and a back metal reflector mating with the front cover on a back side. At 1008, the method can provide uniform thermal irradiation by reflecting infrared light sources forming the one or more heater elements upon a grooved surface of the back metal reflector. In one embodiment, disposing at 1010 can include rotating the substrate apparatus to sequentially feed the substrate within the vacuum chamber and in another embodiment disposing at 1012 can include in-line feeding of the substrate apparatus to sequentially feed the substrate within the vacuum chamber. In another embodiment, forming the absorber layer can include at 1014 the steps of depositing a plurality of copper and gallium atoms over at least a portion of the surface of each one of the plurality of substrates using a first sputtering source, depositing a plurality of selenium atoms over at least a portion of the surface using an evaporation source, depositing a plurality of indium atoms over at least a portion of the surface of each one of the plurality of substrates using a second sputtering source and reacting the plurality of copper, gallium, and indium atoms with the plurality of selenium atoms to form the absorber layer.

According to some embodiments, an apparatus for forming a solar cell includes a housing defining a vacuum chamber of a deposition processing system, and a heating apparatus within the vacuum chamber. The heating apparatus can include one or more heater elements, a front cover covering the one or more heater elements from a front side, and a back metal reflector mating with the front cover on a back side and enclosing the one or more heater elements.

In some embodiments, a heater apparatus for forming a solar cell includes one or more heater elements in a deposition processing system, a front cover covering the one or more heater elements from a front side, and a back metal reflector mating with the front cover on a back side and enclosing the one or more heater elements. In some embodiments, the deposition processing system is a rotating deposition processing system or an in-line deposition processing system, or a vertical deposition processing system. In some embodiments, the heater elements are one of infrared heater elements, microwave tube heating elements, or electric resistive heating elements.

In some embodiments, the back metal reflector is one of planar shaped, arc shaped, or curved shaped. In some embodiments, the back metal reflector is made of a stainless plate and the front cover is made of one of quartz, graphite, silicon carbide, ceramic, or any material having high thermal conductivity. In some embodiments, the back metal reflector is made of a plate having a high-reflectivity metal coating. In some embodiments, the high-reflectivity metal coating is made of one of gold, copper, or aluminum. In some embodiments, the back metal reflector includes grooved elements or alternative shaped elements that enhance a thermal irradiation focus on a substrate or solar cell being processed. In some embodiments, the heater apparatus is placed between adjacent sputtering cathodes of the deposition processing system. In some embodiments, the heater apparatus resides with a housing defining a vacuum chamber of the deposition processing system and wherein the deposition processing system further includes at least a first sputtering source configured to deposit a plurality of absorber layer atoms of a first type over at least a portion of a surface of each one of a plurality of substrates and at least an evaporation source disposed in a first sub-chamber of the vacuum chamber and configured to deposit a plurality of absorber layer atoms of a second type over at least a portion of the surface of each one of the plurality of substrates. In some embodiments, substrates of a plurality of substrates are each sequentially fed in front or above the front quart cover of the heater apparatus for a predetermined period.

In some embodiments, a method of forming a solar cell includes disposing a plurality of substrates about a plurality of surfaces of a substrate apparatus that is operatively coupled to sequentially feed a substrate within a vacuum chamber, forming an absorber layer over a surface of each one of the plurality of substrates, and heating the surface of each one of the plurality of substrates with a heater apparatus having one or more heater elements encased between a front cover covering the one or more heater elements from a front side and a back metal reflector mating with the front cover on a back side. In some embodiments the step of heating includes providing uniform thermal irradiation by reflecting infrared light sources forming the one or more heater elements upon a shaped surface of the back metal reflector constructed to focus thermal radiation towards the surface of a substrate being processed. In some embodiments, the step of disposing includes comprises rotating the substrate apparatus to sequentially feed the substrate within the vacuum chamber. In some embodiments, the step of disposing includes in-line feeding of the substrate apparatus to sequentially feed the substrate within the vacuum chamber. In some embodiments, the step of forming the absorber layer includes depositing a plurality of copper and gallium atoms over at least a portion of the surface of each one of the plurality of substrates using a first sputtering source, depositing a plurality of selenium atoms over at least a portion of the surface using an evaporation source, depositing a plurality of indium atoms over at least a portion of the surface of each one of the plurality of substrates using a second sputtering source, and reacting the plurality of copper, gallium, and indium atoms with the plurality of selenium atoms to form the absorber layer.

various embodiments have been described, it is to be understood that the embodiments described are illustrative only and that the scope of the subject matter is to be accorded a full range of equivalents, many variations and modifications naturally occurring to those of skill in the art from a perusal hereof

Furthermore, the above examples are illustrative only and are not intended to limit the scope of the disclosure as defined by the appended claims. Various modifications and variations can be made in the methods of the present subject matter without departing from the spirit and scope of the disclosure. Thus, it is intended that the claims cover the variations and modifications that can be made by those of ordinary skill in the art.

What we claim is:

1. A heater apparatus for forming a solar cell, comprising:
one or more heater elements in a deposition processing system;
a front cover covering the one or more heater elements from a front side; and
a back metal reflector mating with the front cover on a back side and enclosing the one or more heater elements.

2. The heater apparatus of claim 1, wherein the deposition processing system is a rotating deposition processing system.

3. The heater apparatus of claim 1, wherein the deposition processing system is an in-line deposition processing system.

4. The heater apparatus of claim 1, wherein the deposition processing system is a vertical deposition processing system.

5. The heater apparatus of claim 1, wherein the heater elements are one of infrared heater elements, microwave tube heating elements, or electric resistive heating elements.

6. The heater apparatus of claim 1, wherein the back metal reflector is one of planar shaped, arc shaped, or curved shaped.

7. The heater apparatus of claim 1, wherein the heater apparatus is placed between adjacent sputtering cathodes of the deposition processing system.

8. The heater apparatus of claim 1, wherein substrates of a plurality of substrates are each sequentially fed in front or above the front quart cover of the heater apparatus for a predetermined period.

9. The heater apparatus of claim 1, wherein the back metal reflector is made of a stainless plate and the front cover is made of one of quartz, graphite, silicon carbide, ceramic, or any material having high thermal conductivity.

10. The heater apparatus of claim 1, wherein the back metal reflector includes grooved elements or alternative shaped elements that enhance a thermal irradiation focus on a substrate or solar cell being processed.

11. The heater apparatus of claim 1, wherein the back metal reflector is made of a plate having a high-reflectivity metal coating.

12. The heater apparatus of claim 11, wherein the high-reflectivity metal coating is made of one of gold, copper, or aluminum.

13. The heater apparatus of claim 11, wherein the back metal reflector includes grooved elements.

14. The heater apparatus of claim 1, wherein the heater apparatus resides with a housing defining a vacuum chamber of the deposition processing system and wherein the deposition processing system further includes at least a first sputtering source configured to deposit a plurality of absorber layer atoms of a first type over at least a portion of a surface of each one of a plurality of substrates and at least an evaporation source disposed in a first subchamber of the vacuum chamber and configured to deposit a plurality of absorber layer atoms of a second type over at least a portion of the surface of each one of the plurality of substrates.

15. A method of forming a solar cell, comprising:
disposing a plurality of substrates about a plurality of surfaces of a substrate apparatus that is operatively coupled to sequentially feed a substrate within a vacuum chamber;
forming an absorber layer over a surface of each one of the plurality of substrates; and
heating the surface of each one of the plurality of substrates with a heater apparatus having one or more heater elements encased between a front cover covering the one or more heater elements from a front side and a back metal reflector mating with the front cover on a back side.

16. The method of claim 15, wherein the step of heating comprises providing uniform thermal irradiation by reflecting infrared light sources forming the one or more heater elements upon a shaped surface of the back metal reflector constructed to focus thermal radiation towards the surface of a substrate being processed.

17. The method of claim 15, wherein the disposing comprises rotating the substrate apparatus to sequentially feed the substrate within the vacuum chamber.

18. The method of claim 15, wherein the disposing comprises in-line feeding of the substrate apparatus to sequentially feed the substrate within the vacuum chamber.

19. The method of claim 15, wherein the step of forming the absorber layer comprises:
depositing a plurality of copper and gallium atoms over at least a portion of the surface of each one of the plurality of substrates using a first sputtering source;
depositing a plurality of selenium atoms over at least a portion of the surface using an evaporation source;
depositing a plurality of indium atoms over at least a portion of the surface of each one of the plurality of substrates using a second sputtering source; and
reacting the plurality of copper, gallium, and indium atoms with the plurality of selenium atoms to form the absorber layer.

20. An apparatus for forming a solar cell, comprising:
a housing defining a vacuum chamber of a deposition processing system;
a heating apparatus within the vacuum chamber, the heating apparatus comprising:
one or more heater elements;
a front cover covering the one or more heater elements from a front side; and
a back metal reflector mating with the front cover on a back side and enclosing the one or more heater elements.
